(19) United States
(12) Patent Application Publication
(10) Pub. No.: US 2016/0145748 A1
(43) Pub. Date: May 26, 2016

(54) HIGH SPEED SEQUENTIAL CATHODIC PROTECTION SYSTEMS AND METHODS

(71) Applicants: Jon-Michael BRAND, Denver, CO (US); Will Anders BIERWIRTH, Rock Springs, WY (US); James Paul REDDEN, Stillwater, OK (US); Trent Michael PULLIAM, Denver, CO (US); Brandon Steward LANGLEY, Guthrie, OK (US)

(72) Inventors: Jon-Michael BRAND, Denver, CO (US); Will Anders BIERWIRTH, Rock Springs, WY (US); James Paul REDDEN, Stillwater, OK (US); Trent Michael PULLIAM, Denver, CO (US); Brandon Steward LANGLEY, Guthrie, OK (US)

(73) Assignee: BRAND SERVICES, LLC, Kennesaw, GA (US)

(21) Appl. No.: 14/946,923

(22) Filed: Nov. 20, 2015

Related U.S. Application Data
(60) Provisional application No. 62/082,248, filed on Nov. 20, 2014.

(51) Int. Cl. C23F 13/04; C23F 13/20; H01L 31/042

(52) U.S. Cl. CPC C23F 13/04; H01L 31/042; C23F 13/20

(57) ABSTRACT

High speed cathodic protection control systems and methods provide for the delivery of deliver electrical current to a group of metal structures, such as well casings, in a sequential manner to prevent corrosion. A plurality of relays allow electrical current to flow from a power supply to subsets of the group of metal structures. The flow of electrical current is controlled by a microntroller which controls the relays to allow delivery of the electrical current at high speeds for short periods of time from the power supply to subsets of the group of metal structures in a sequential manner.

### CROSS-REFERENCE TO RELATED APPLICATION

This application claims the benefit of U.S. Provisional Patent Application Ser. No. 62/082,248, filed Nov. 20, 2014, the entirety of which is hereby incorporated herein by reference in its entirety for all purposes.

### TECHNICAL FIELD

The present invention relates generally to the field of corrosion and systems and methods for controlling corrosion, and more particularly to an electronic controller system and method for providing cathodic protection.

### BACKGROUND

Corrosion is a naturally occurring phenomenon commonly defined as the deterioration of a substance (usually a metal) or its properties because of a reaction with its environment. Metallic surfaces exposed to an electrolyte have a multitude of microscopic anodic and cathodic sites. Where anodes are more electronegative than cathodes, a potential difference is created between them. Corrosion occurs as a result of an electrochemical reaction driven by the potential difference between the anode and the cathode.

Cathodic protection is used to control corrosion of metal objects by reducing the potential difference between anodes and cathodes to a negligible value. Cathodic protection can be accomplished by sending a current into the metal structure to be protected from an external electrode and polarizing the cathodic sites in an electronegative direction. This makes the metal structure work as the cathode of an electrochemical cell or electronic system. Cathodic protection is most commonly used to protect metal objects buried in the ground or water, such as fuel pipelines and storage tanks, steel pier piles, ship hulls, offshore oil platforms, and on shore well casings.

When metal objects to be protected from corrosion are closely spaced together, this creates a challenge for applying cathodic protection. For example, well casings that are closely spaced tend to have increased resistance as electrical current increases, resulting in mutual interference. This is commonly known as the “crowding effect”. This mutual interference can cause incomplete protection of well casings, or it can damage a casing.

It is to the provision of a cathodic protection system for eliminating or reducing the crowding effect that the present invention is primarily directed.

### SUMMARY

In example embodiments, the present invention relates to high speed sequential cathodic protection systems and methods for delivering electrical current to individual metal structures, such as well casings, at high speeds for short periods of time, in a sequential manner.

In an example form, the present invention relates to high speed cathodic protection system for delivering electrical current to a well casing group having a plurality of individual well casings. The system includes a power supply, a plurality of relays, and a microcontroller. In example forms, the plurality of relays are adapted to allow electrical current to flow from the power supply to subsets of the group of metal structures. The microcontroller is configured to control the relays to allow delivery of the electrical current at high speeds for short periods of time from the power supply to subsets of the group of metal structures in a sequential manner.

In an example form, the microcontroller is configured for a single well operation mode, such that the electrical current only passes to one of the plurality of individual well casings at a time. In another form, the microcontroller is configured for a double well operation mode, such that the electrical current can pass to two non-adjacent well casings of the plurality of individual well casings at a time. Optionally, the microcontroller is configured for an all on operation mode, such that the electrical current passes to each of the plurality of individual well casings and is divided equally among each of the well casings.

These and other aspects, features and advantages of the invention will be understood with reference to the drawing figures and detailed description herein, and will be realized by means of the various elements and combinations particularly pointed out in the appended claims. It is to be understood that both the foregoing general description and the following brief description of the drawings and detailed description of the invention are exemplary and explanatory of preferred embodiments of the invention, and are not restrictive of the invention, as claimed.

### BRIEF DESCRIPTION OF THE DRAWINGS

FIG. 1 is a schematic wiring diagram of a high speed sequential cathodic protection system according to an example embodiment of the present invention.

FIG. 2 is a cross-sectional view of a plurality of well casings to which a cathodic protection system according to an example embodiment of the present invention may be applied.

FIG. 3 is a flow chart depicting a method for providing high speed sequential cathodic protection according to an example embodiment of the present invention.

### DETAILED DESCRIPTION OF EXAMPLE EMBODIMENTS

The present invention may be understood more readily by reference to the following detailed description of the invention taken in connection with the accompanying drawing figures, which form a part of this disclosure. It is to be understood that this invention is not limited to the specific devices, methods, conditions or parameters described and/or shown herein, and that the terminology used herein is for the purpose of describing particular embodiments by way of example only and is not intended to be limiting of the claimed invention. Any and all patents and other publications identified in this specification are incorporated by reference as though fully set forth herein.

Also, as used in the specification including the appended claims, the singular forms “a,” “an,” and “the” include the plural, and reference to a particular numerical value includes at least that particular value, unless the context clearly dictates otherwise. Ranges may be expressed herein as from “about” or “approximately” one particular value and/or to “about” or “approximately” another particular value. When such a range is expressed, another embodiment includes from the one particular value and/or to the other particular value. Similarly, when values are expressed as approximations, by use of the antecedent “about,” it will be understood that the particular value forms another embodiment.

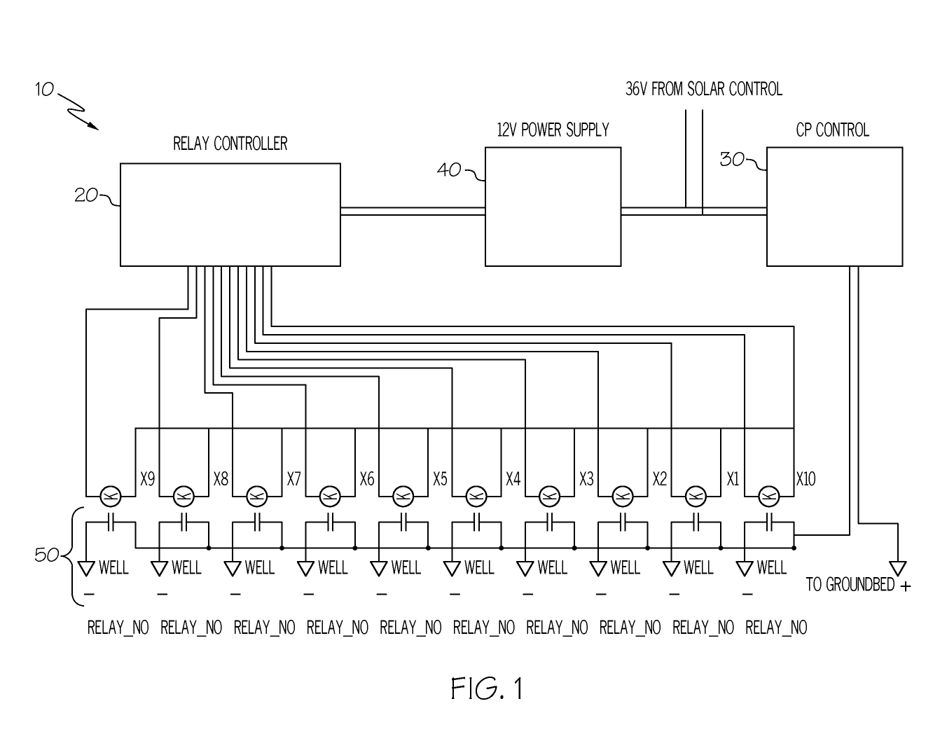

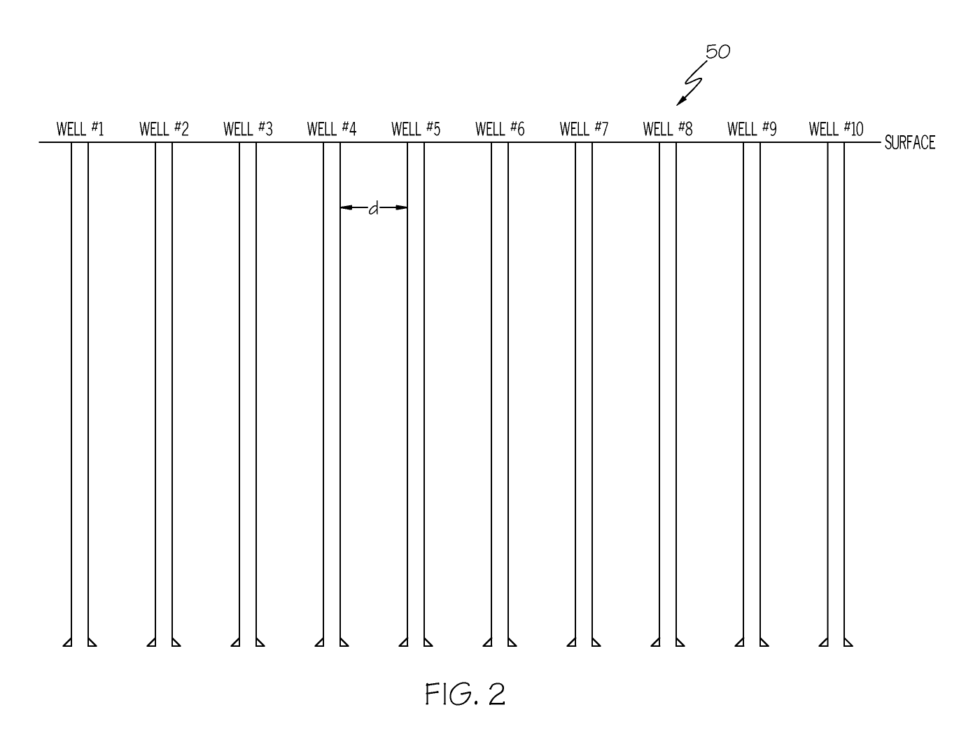

With reference now to the drawing figures, wherein like reference numbers represent corresponding parts throughout the several views, FIG. 1 shows a schematic wiring diagram of a high speed sequential cathodic protection system 10 according to an example embodiment of the present invention. As depicted, the high speed sequential cathodic protection system 10 is preferably provided for providing protective electrical current to a plurality of well casings 50, shown in detail in FIG. 2.

In one example form, the sequential cathodic protection system 10 includes a relay controller 20, which may comprise an 8 bit microcontroller that operates multiple solid-state high current relays X1-X10. In one example, the relays may be normally open (NO), as indicated inn FIG. 1.

The sequential cathodic protection system also includes a cathodic protection (CP) controller 30 that is connected to each well casing and to a ground bed which may include one or more buried anodes to force the electrical current to flow through the well casings 50. The well casings 50 are depicted in detail FIG. 2 as Well #1-Well #10 (also referred to herein as well casings W1-W10). As shown in FIG. 2, each well casing is separated from an adjacent well casing by a distance d.

Referring again to FIG. 1, The CP controller 30 allows the electrical current to be supplied to the well casings W1-W10. from a power supply, when the corresponding relays X1-X10 are closed. The amplitude of electrical current may be adjusted as needed. The CP controller 30 may also be implemented with a microcontroller.

The power supply to which the controllers 20 and 30 are connected includes at least one power supply, for example, a 36 volt source from a solar panel and/or a 12 volt (AC or DC) source 40. Optionally, an array of one or more solar panels may charge a bank of one or more batteries for storing electrical energy to be used in delivering electrical current for cathodic protection in the system.

Generally, each solid-state high current relay is associated with an individual well casing of the plurality of well casings W1-W10 such that, in a closed state, an individual relay allows current to flow through an associated well casing. For example, as can be understood with reference to FIGS. 1 and 2, well casing W1 is associated with relay X1, well casing W2 is associated with relay X2, well casing W3 is associated with relay X3, well W4 is associated with relay X4, well casing W5 is associated with relay X5, well casing W6 is associated with relay X6, well casing W7 is associated with relay X7, well casing W8 is associated with relay X8, well casing W9 is associated with relay X9, and well casing W10 is associated with relay X10.

According to example embodiments of the present invention, by sequencing the protection to the well casings W1-W10, the crowding effect is eliminated due to only one well casing receiving electrical current at a time. In example forms, each well casing is provided with protective electrical current for a few milliseconds at a time. According to one form, the relay controller 20 controls the relays X1-X10 to cause the relays to close and open to switch the electrical current supplied by the CP controller 30 from one adjacent well casing to the other. For example, the relay controller causes the relay X1 to close, while the relays X2-X10 are open, causing electrical current to flow through the well casing W1. Then, the relay controller 20 causes the relay X1 to open and the relay X2 to close, causing electrical current to flow through the well casing W2. Next, the relay controller causes the relay X2 to open and the relay X3 to close, causing the electrical current to flow through the well casing W3. This closing and opening of relays continues until each well casing has received a short span of electrical current. The relay controller 20 then recycles and starts back with closing the relay X1 to cause current to flow through the well casing W1 and repeats.

In example forms, the amount of time the electrical current is applied to the individual well casings W1-W10 can be variable, for example, between about 1-200,000 microseconds. According to an illustrative embodiment, the variable time will allow a user or operator of the system 10 to adjust the relay controller 20 to provide the greatest protection to the well casings.

Optionally, the system 10 may have various modes of operation other than the single well mode described above. For example, the system 10 may have, in addition or instead of a single well mode, a double (or triple, etc.) well mode, and/or an all on well mode. The single well operation mode allows current to pass to only one well casing at a time, for example, as described above. The double well operation mode allows current to pass to two or more non-adjacent well casings at the same time, for example, W1 and W3, W1 and W7, W6 and W10, or any two or more well casings that are not adjacent to one another. The all on operation mode enables the individual relays to allow current to be divided equally among the well casings. In example forms, the all on operation mode can be used to set the total cathodic protection current.

In additional example embodiments, the well casings can comprise more or less than ten well casings as depicted. Thus, the number of relays is generally about the same as the number of well casings.

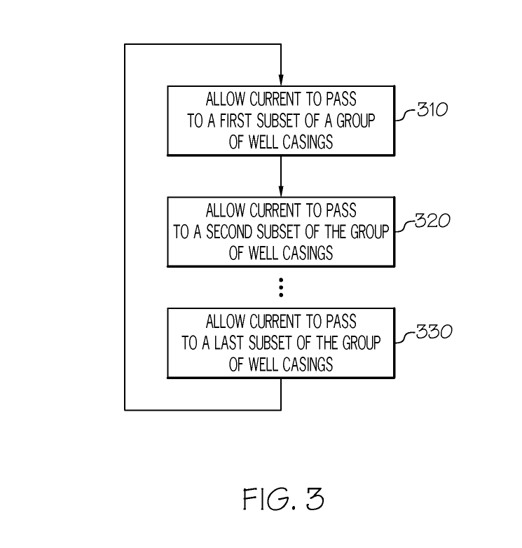

FIG. 3 is a flow chart depicting a method for providing high speed cathodic protection according to an example embodiment. At step 310, the relay controller 20 controls a subset of relays, e.g., relay X1, to allow current to pass to a first subset of a group of well casings, e.g., well casing W1. At step 320, the relay controller 20 controls another subset of relays, e.g., relay X2, to allow current to pass to a second subset of the group of well casings, e.g., well casing W2. The process repeats until, at step 330, the relay controller 20 controls a last subset of relays, e.g., relay X10, to allow current to pass to a last subset of well casings, e.g., well casing W10. Then, the process returns to step 310 and repeats such that current is delivered to each subset of well casings in a sequential manner.

Although the method depicted in FIG. 3 is described with respect to single mode operation for illustrative purposes, it should be appreciated that similar steps may be followed for double, triple, etc. mode operation.

Although the description above is directed to cathodic protection of well casings, it should be appreciated that the invention is not limited to this application. The principles described above may be applied to cathodic protection of any underground metal structure including, e.g., pipelines.

While the invention has been described with reference to preferred and example embodiments, it will be understood by those skilled in the art that a variety of modifications, additions and deletions are within the scope of the invention, as defined by the following claims.

What is claimed is:

1. A high speed sequential cathodic protection system for delivering electrical current to a group of underground metal structures comprising a plurality of individual metal structures to prevent corrosion of the metal structures, the system comprising:
a power supply;
a plurality of individual relays adapted to allow electrical current to flow from the power supply to subsets of the group of metal structures; and
a microcontroller configured to control the relays to allow delivery of the electrical current at high speeds for short periods of time from the power supply to subsets of the group of metal structures in a sequential manner.

2. The high speed cathodic protection system of claim 1, wherein the metal structures include well casings.

3. The high speed cathodic protection system of claim 1, wherein each individual relay is adapted to be closed to allow electrical current to pass through an individual metal structure associated with the relay and opened to prevent electrical current from passing through the individual metal structure associated with the relay.

4. The high speed cathodic protection system of claim 1, further comprising a cathode protection controller connected to the power supply, the metal structures, and a ground bed, wherein the cathodic protection controller delivers the electrical current to the metal structure when a relay associated with the metal structure is closed.

5. The high speed cathodic protection sequencer system of claim 1, wherein the microcontroller controls the individual relays such that the electrical current only passes to one of the plurality of individual metal structures at a time.

6. The high speed cathodic protection system of claim 1, wherein the microcontroller controls the individual relays such that the electrical current passes to at least two non-adjacent metal structures of the plurality of individual metal structures at a time.

7. The high speed cathodic protection system of claim 1, wherein the microcontroller controls the individual relays such that the electrical current passes to each of the individual metal structures and is divided equally among each of the metal structures.

8. The high speed cathodic protection system of claim 1, wherein the power supply comprises a solar panel.

9. The high speed cathodic protection system of claim 1, wherein an amount of time that the electrical current is passed to a metal structure is variable.

10. A high speed cathodic protection sequencer for controlling delivery of electrical current to a group of underground metal structures comprising a plurality of individual metal structures, to prevent corrosion of the metal structures, the sequencer comprising:
a plurality of relays adapted to allow electrical current to flow from a power supply to subsets of the group of metal structures; and
a microcontroller configured to control the relays to allow delivery of the electrical current at high speeds for short periods of time from a power supply to subsets of the group of metal structures in a sequential manner.

11. The high speed cathodic protection sequencer of claim 10, wherein the metal structures are well casings.

12. The high speed cathodic protection sequencer of claim 10, wherein each individual relay is adapted to be closed to allow electrical current to pass through an associated individual metal structure and opened to prevent electrical current from passing through the associated individual metal structure.

13. The high speed cathodic protection sequencer of claim 10, wherein the microcontroller controls the individual relays such that the electrical current only passes to one of the plurality of individual metal structures at a time.

14. The high speed cathodic protection sequencer of claim 10, wherein the microcontroller controls the individual relays such that the electrical current passes to at least two non-adjacent metal structures of the plurality of individual metal structures at a time.

15. The high speed cathodic protection sequencer of claim 10, wherein the microcontroller controls the individual relays such that the electrical current passes to each of the individual metal structures and is divided equally among each of the metal structures.

16. A method of providing cathodic protection for a plurality of individual metal structures, the method comprising controlling, by a microcontroller, sequential application of an electrical current to subsets of the metal structure group comprising at least one of the individual metal structures at a time, at high speeds for short periods of time.

17. The method of claim 16, wherein application of the electrical current is controlled such that the electrical current passes to at least two non-adjacent metal structures of the plurality of individual metal structures at a time.

18. The method of claim 16, wherein application of the electrical current is controlled such that the electrical current passes to each of the individual metal structures and is divided equally among each of the well casings.

19. The method of claim 16, wherein an amount of time that the electrical current is passed to a metal structure is variable.
